(19) United States
(12) Patent Application Publication
(10) Pub. No.: US 2015/0207481 A1
(43) Pub. Date: Jul. 23, 2015

(54) GENRE DEPENDENT AUDIO LEVEL CONTROL

(71) Applicants: Sven Duwenhorst, Hamburg (DE); Holger Classen, Hamburg (DE)

(72) Inventors: Sven Duwenhorst, Hamburg (DE); Holger Classen, Hamburg (DE)

(73) Assignee: ADOBE SYSTEMS INCORPORATED, San Jose, CA (US)

(21) Appl. No.: 11/941,526

(22) Filed: Nov. 16, 2007

(51) Int. Cl. H03G 3/20

(52) U.S. Cl. CPC H03G 3/20

(57) ABSTRACT

Systems, methods, and computer program products relating to digital audio data are provided. In some implementations a method is provided. The method includes receiving a selection of an audio score, the audio score being a decomposed digital audio data template associated with one or more audio tracks, automatically identifying score information for the selected audio score, generating the selected audio score including retrieving the one or more tracks of digital audio data associated with the audio score, and modifying the settings of at least one of one or more post processors using the identified score information, where the modified settings provide an audio output level within a specified range. Other embodiments of the aspect include systems and computer program products.

### BACKGROUND

The present disclosure relates to digital audio data.

Digital audio data can include audio data in different digital audio tracks. Tracks are typically distinct audio files. Tracks can be generated mechanically (e.g., using a distinct microphone as an input source for each track), synthesized (e.g., using a digital synthesizer), or generated as a combination of any number of individual tracks. Tracks can be combined by mixing the separate digital audio tracks into a single mixdown track. A number of audio tracks can be used to form a score. A score is decomposed digital audio data template including multiple tracks that can be rearranged to a desired duration and intensity.

A track includes one or more channels (e.g., a stereo track can include two channels, left and right). A channel is a stream of audio samples. For example, a channel can be generated by converting an analog input from a microphone into digital samples using a digital analog converter.

Particular audio data (e.g., the audio data of a particular track) has a level value based on the energy that is contained in the audio data. This level value is referred to as a root mean square (RMS) value of the audio data. The output level of the audio data is the level value of the mixdown track following mixing and post-processing of the audio data. The audio data also has a peak value describing a maximum amplitude value for the audio data within a specified time (e.g., one period of an audio waveform of the audio data). The ratio of the peak value and the RMS value over a specified time for the audio data is referred to as a crest factor. A high crest factor indicates audio peak intensities that are higher than the RMS value for the audio data.

Additionally, the audio data of one or more tracks can be edited. A user can apply different processing operations to portions of the audio data to generate particular audio effects. For example, the digital audio data can be adjusted by a user to increase amplitude of the audio data for a particular track (e.g., by increasing the overall intensity of the audio data) across time. This is typically referred to as applying a gain to the audio data. In another example, the amplitude of audio data can be adjusted over a specified frequency range. This is typically referred to as equalization.

### SUMMARY

This specification describes technologies relating to digital audio data.

In general, in one aspect, a method is provided. The method includes receiving a selection of an audio score, the audio score being a decomposed digital audio data template associated with one or more audio tracks, automatically identifying score information for the selected audio score, generating the selected audio score including retrieving the one or more tracks of digital audio data associated with the audio score, and modifying the settings of at least one of one or more post-processors using the identified score information, where the modified settings provide an audio output level within a specified range. Other embodiments of the aspect include systems and computer program products.

Implementations of the aspect can include one or more of the following features. The score information can include a genre and modifying settings for one or more post-processors can further include identifying the genre of the score of a plurality of distinct genres and identifying settings for at least one of the one or more post-processors corresponding to the identified genre. Identifying settings can include using a table relating genres with settings for one or more post-processors. The one or more post-processors can include a limiter. Modifying the settings of the limiter can include modifying a limiter threshold value and a limiter gain according to the score information. The aspect can further include reading metadata associated with the score, the metadata including the score information. The settings can be modified for each distinct genre such that all genres provide an audio output level within the specified range.

In general, in one aspect, a method is provided. The method includes receiving a selection of two or more related digital audio tracks, automatically identifying information associated with the two or more audio tracks, the information including a type of audio data, and modifying the settings of at least one of one or more post processors using the identified information, where the modified settings provide an audio output level within a specified range for audio data mixed from the two or more audio tracks. Other embodiments of the aspect include systems and computer program products.

Particular embodiments of the subject matter described in this specification can be implemented to realize one or more of the following advantages. Scores can be generated having genre dependent output levels. Post-processing of the audio data for each score can be modified to provide consistent output levels across genres within a specified range. Score information including genre can be automatically identified. Post-processor values can be automatically changed according to a genre of the audio data. Consequently, the perceived intensity of the audio data (i.e., loudness) can be substantially the same for each genre. A user can switch between scores of different genres without substantial changes in the loudness of the output. Different scores of the same genre or different genres can be corrected to have the same loudness. Additionally, the perceived loudness can be increased for different scores having a known genre. When mixed audio data exceeds a maximum limit, genre information can be used to compress the audio data while minimizing the effect on overall loudness.

The details of one or more embodiments of the invention are set forth in the accompanying drawings and the description below. Other features, aspects, and advantages of the invention will become apparent from the description, the drawings, and the claims.

### BRIEF DESCRIPTION OF THE DRAWINGS

FIG. 1 is a flowchart showing an example method for genre dependent level control.

FIG. 2 is a flowchart showing an example method for genre dependent post-processor setup.

FIG. 3 is a block diagram illustrating an example relationship between genres and post-processor settings.

FIG. 4 is a block diagram of an example system.

Like reference numbers and designations in the various drawings indicate like elements.

### DETAILED DESCRIPTION

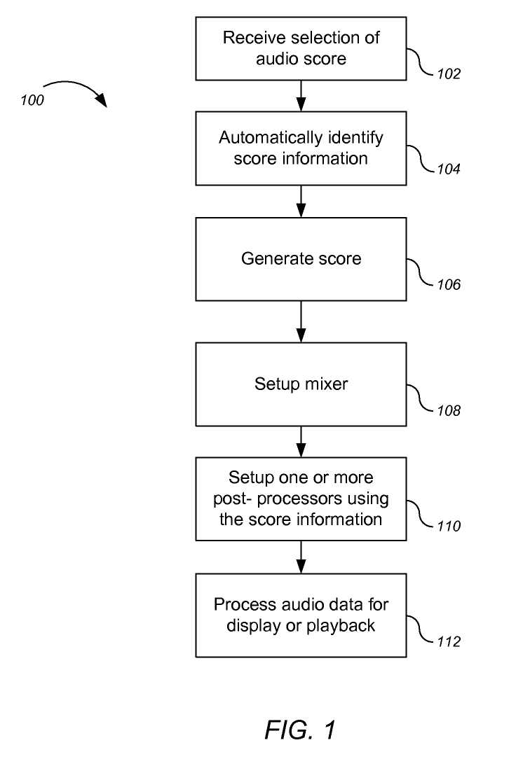

FIG. 1 is a flowchart showing an example method 100 for genre dependent level control. For convenience, the method 100 will be described with respect to a system that performs the method 100. The system receives a selection 102 of an audio score. The selection of the audio score can be received in response to a user input to the system. For example, the system can include a digital audio workstation including a music creation tool that allows a user to create music using a selected score. The user can select the score from a collection of scores. For example, a user can open a new composition project using the selected score as a template. In some implementations, the selected score is retrieved from a storage device local or remote to the system.

The system identifies 104 information for the selected score. In some implementations, the score information is read from score metadata. The score information can include, for example, a score name, copyright, version, author, and genre of the score. Each score can have a particular genre. Each genre identifies a type of music associated with the score. Examples of genres can include jazz, classical, rock, pop, and wedding. In some implementations, the number of genres is open-ended. Thus, new scores can be created that have new genres. Other information about the selected score can include an identification of one or more audio files associated with the selected score. Each of the audio files can include one or more tracks.

The system generates 106 the selected score. Generating the selected score includes retrieving the one or more audio files associated with the score. The retrieved audio files can be added to a composing project that can be displayed and manipulated by a user (e.g., edited).

For example, a visual representation of each track of audio data for the composing project can be displayed. The system can display the visual representation the audio data for one or more of the tracks with respect to a feature of the audio data (e.g., amplitude, frequency, phase), on a feature axis (e.g., on the y-axis) and with respect to time (e.g., in seconds), on a time axis (e.g., on the x-axis).

The audio data of one or more tracks can be edited (e.g., based on a user input). For example, the system can apply a particular effect to specified audio data of one or more tracks. In some implementations, specific portions of the audio data in a track can be selected and edited independently of the other audio data in the track. For example, the user can select a region of the visual representation of the audio data and apply a particular editing effect (e.g., a gain increase) to the audio data corresponding to the selected region of the visual representation. In some implementations, an input is received when the score is selected specifying a time length for the score. Each retrieved track associated with the score is automatically resized in length to correspond to the specified time length before displaying the audio data. Alternatively, a user can adjust the length of the displayed audio data later as an editing operation.

In some implementations, the system performs 108 setup operations for a mixer. The mixer defines how the tracks of the audio data will be combined together. For example, the mixer defines how the individual tracks can be summed together into a mixdown track that includes audio data from each component track. Additionally, as part of or following mixing, a number of post processing steps can be applied to the mixed audio data by specific post-processors including equalizers, compressors, and limiters.

Each score results in a particular output level when the associated tracks are mixed. However, the output level can vary between scores and in particular between scores of different genres. For example, different authors can create scores having different pre-mixed audio parameters (e.g., amplitude values) that result in a particular mixed output level. Also, scores can be created by different third-party entities having different initial output levels. Additionally, user edits of the audio tracks of the score can change the output level of the mixdown track. The system modifies 110 the settings of one or more post-processors according to the identified score information, for example using score metadata including the genre of the score.

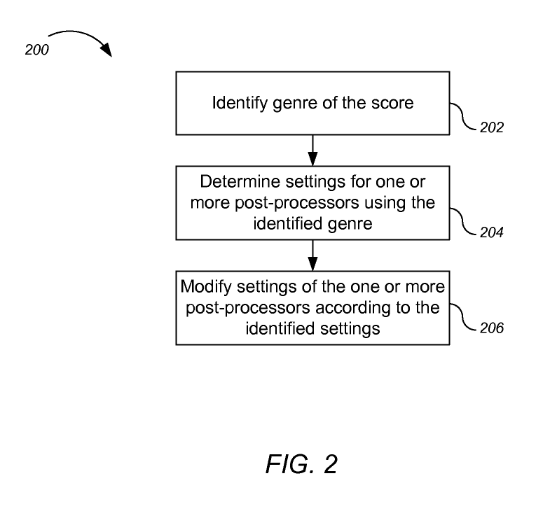

FIG. 2 is a flowchart showing an example method 200 for genre dependent post-processor setup. For convenience, the method 200 will be described with respect to a system that performs the method 200. The system identifies 202 the genre of the score. In some implementations, the system automatically identifies the score information. The genre can be identified, for example, according to score information provided as score metadata. In some implementations, the genre of the score is the only score information used as a parameter for post-processor setup.

In some other implementations, one or more additional score parameters from the score information are used in addition to or in place of genre. For example, scores having a same genre but different authors can be treated differently because the different authors can create scores having different audio parameters even within the same genre. As a result, the system can identify both the genre and the author and for use in post-processor setup. Similarly, the date associated with a particular score can be used by the system.

The system determines 204 settings for controlling one or more post-processors using the identified score information. The values for the post-processor settings can be specified in order to produce an output level of the audio data in the mixdown track within a specified range. The scores for different genres can be generated with pre-mixed values that vary by genre. Thus, the output level can change from one genre to the next. The identified settings control the post-processors to compensate for the different output levels provided, for example by scores of different genres, according to the particular score information such that different genres provide output levels within the specified range.

The settings are determined, for example, using a lookup table that includes particular post-processors settings according to the identified score information. For example, if the identified score information is the genre of the score, the lookup table can include settings for one or more of the post-processors that are specific to the genre. In some implementations, the table includes an “any other” genre that corresponds to any genre identified in score that does not match the genres of the table. Thus, scores having new or non-included genres can be compensated without having previously defined post-processor settings for that particular genre. In some implementations, when more than one score parameter is used, a more complex table is formed that relates both score parameters with different post-processor settings. For example, if both the genre and author are used as parameters, the table can include separate post-processor settings for each genre/author combination.

A limiter post-processor, for example, can include settings for a threshold value and a gain value. Different values for the settings can be specified for different genres as well as for other score parameters or combinations of score parameters. In some implementations, the limiter gain setting provides a specific gain to the audio data of the mixdown track. The gain increase can cause a corresponding increase in the output level. The amount of gain increase can be determined in order to increase the output level to a specified range that corresponds to a perceived loudness that is similar across scores of different score parameters (e.g., different genres).

The limiter threshold level defines an intensity level below which all audio data is unchanged. Audio data above the threshold level, however, is clipped. In particular, when summing audio data from multiple tracks, it is possible to get a summed peak in the audio data that has an audio level that exceeds 0 decibels full scale, 0 dBFS, (e.g., according to a scale where the maximum audio intensity is 0 dB and the minimum audio intensity is negative infinity). Although the digital value of the audio data can be greater than 1 (e.g., when defined by a 32 bit floating point value), limitations of audio devices (e.g., a digital-analog converter) prevent the audio data from being reproduced. Instead, the audio becomes clipped to the maximum level that is reproducible. The limiter prevents values from exceeding 0 dB full scale including clipping the peaks of the audio data that exceed the threshold value (e.g., to the threshold intensity level). Consequently, the perceived loudness can be increased while reducing the overall dynamic range of the audio data. Additionally, the gain increase provided by the limiter typically increase the RMS of the audio data such that the overall crest factor typically decreases.

The lookup table can include settings for other post-processors including equalizers and compressors. The compressor, for example, can include an amount of attenuation to apply to audio data that exceeds a threshold value. For example, if the range of output level values specified for the audio data of all genres is less than the output level for the audio data of a score having a specific genre, the audio data can be compressed such that the output level is within the specified range. Thus, loudness can be preserved across genres having an initial output level value that is either too high or too low. The equalizer can selectively apply a gain or compression to particular frequencies of the audio data. For example, a three band parametric equalizer (e.g., low frequencies, middle frequencies, and high frequencies) can have zero application at each band for a classic genre. A pop genre, however, can have an equalizer that increases gain at high and low frequencies while attenuating at middle frequencies.

The system automatically modifies 206 the settings of the one or more post-processors according to the determined settings (e.g., to control the particular post-processor based on the score information. For example, the post-processors can have default settings that are modified according to the identified genre-specific settings. In some implementations, not all of the post-processors are modified. For example, a particular genre can only have identified settings for a particular post-processor, while leaving other post-processors unchanged. In that case, the remaining post-processors retain their default values. The post-processors are then applied to the audio data of the mixdown track in order to provide a particular output level. In some alternative implementations, the post processors applied to particular audio data can be set by a user. For example, the user can identify particular post-processing to apply.

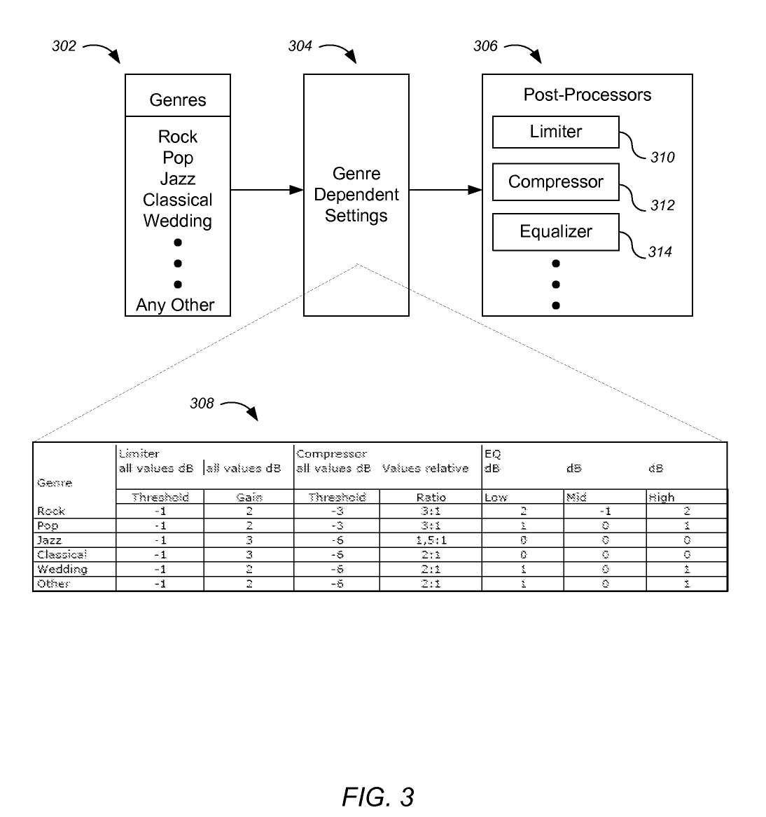

FIG. 3 is a block diagram illustrating an example relationship between genres and post-processor settings. FIG. 3 includes a collection of genres 302. The collection of genres 302 includes rock, pop, jazz, classical, wedding, and others. The particular genres only illustrate examples. Additionally, the collection of genres 302 includes an “any other” genre for use, for example, when a particular score has a genre that doesn't match any genre in the collection of genres 302. The collection of genres 302 can include other genres in addition to or in place of those shown in FIG. 3. The genres are associated with genre dependent settings 304. Once the genre dependent settings 304 are identified for a particular score having a genre from the collection of genres 302, post-processors 306 can be modified according to the genre dependent settings. The post-processors 306 include, for example, a limiter 310, a compressor 312, and an equalizer 314. In some implementations, other post-processors are provided.

An example of the genre dependent settings 304 is shown for a limiter, a compressor, and an equalizer post-processor as table 308. The table 308 includes a list of genres, one for each row of the table 308 and columns corresponding to limiter settings, compressor settings, and equalizer settings. For example, for each genre, the table 308 includes limiter settings including values for the threshold and gain settings. These values are then substituted into the limiter post processor 310. For example, the threshold and gain values for the “rock” genre are −1 dB and 2 dB, respectively.

As shown in FIG. 1, the system processes 112 audio data for display or playback. For example, the audio data can be displayed as separate tracks or as a single mixdown track formed by combining the individual tracks of the score according to the particular mixing topology. The audio data can be mixed and stored on another device for playback or played directly. The playback can have an output level that has been modified according to the identified genre dependent settings. In some implementations, the user can edit the individual tracks. For example, the user can increase the gain for part of a single track. However, after mixing the post-processors can act according to the genre dependent settings to provide a consistent output level after editing. Thus, the output level can remain within the specified range even if the individual tracks of the score are edited. The audio data of the score can be separately saved for later editing or playback.

In some alternative implementations, a score is not used. Instead, the techniques can be applied to any multi-track audio including two or more related tracks. Additionally, the related tracks can be identified as having a particular type. For example, the tracks can be identified in metadata (e.g., input by the user) as belonging to a particular genre (e.g., classical). The metadata information about the tracks can be used as shown in FIGS. 1-2 to modify the post processing of the mixed tracks in order to provide a particular output.

Embodiments of the subject matter and the functional operations described in this specification can be implemented in digital electronic circuitry, or in computer software, firmware, or hardware, including the structures disclosed in this specification and their structural equivalents, or in combinations of one or more of them. Embodiments of the subject matter described in this specification can be implemented as one or more computer program products, i.e., one or more modules of computer program instructions encoded on a computer-readable medium for execution by, or to control the operation of, data processing apparatus. The computer-readable medium can be a machine-readable storage device, a machine-readable storage substrate, a memory device, a composition of matter effecting a machine-readable propagated signal, or a combination of one or more of them. The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. A propagated signal is an artificially generated signal, e.g., a machine-generated electrical, optical, or electromagnetic signal, that is generated to encode information for transmission to suitable receiver apparatus.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio player, a Global Positioning System (GPS) receiver, to name just a few. Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described is this specification, or any combination of one or more such back-end, middleware, or front-end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other.

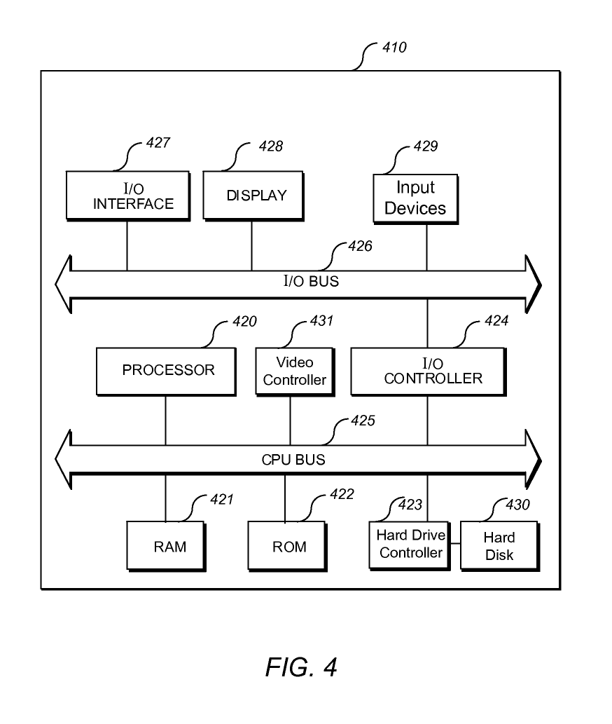

An example of one such type of computer is shown in FIG. 4, which shows a block diagram of a programmable processing system (system) 410 suitable for implementing apparatus or performing methods of various aspects of the subject matter described in this specification. The system 410 includes a processor 420, a random access memory (RAM) 421, a program memory 422 (for example, a writable read-only memory (ROM) such as a flash ROM), a hard drive controller 423, a video controller 431, and an input/output (I/O) controller 424 coupled by a processor (CPU) bus 425. The system 410 can be preprogrammed, in ROM, for example, or it can be programmed (and reprogrammed) by loading a program from another source (for example, from a floppy disk, a CD-ROM, or another computer).

The hard drive controller 423 is coupled to a hard disk 430 suitable for storing executable computer programs, including programs embodying aspects of the subject matter described in this specification.

The I/O controller 424 is coupled by means of an I/O bus 426 to an I/O interface 427. The I/O interface 427 receives and transmits data (e.g., stills, pictures, movies, and animations for importing into a composition) in analog or digital form over communication links such as a serial link, local area network, wireless link, and parallel link.

Also coupled to the I/O bus 426 is a display 428 and an input device 429 (e.g., a keyboard or a mouse). Alternatively, separate connections (separate buses) can be used for the I/O interface 427, display 428, and input device 429.

While this specification contains many specifics, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the invention have been described. Other embodiments are within the scope of the following claims. For example, the actions recited in the claims can be performed in a different order and still achieve desirable results.

What is claimed is:

1. A method comprising:
receiving a selection of an audio score, the audio score being a decomposed digital audio data template associated with one or more audio tracks;
automatically identifying score information for the selected audio score, where the score information includes a genre and an author;
generating the selected audio score including retrieving the one or more tracks of digital audio data associated with the audio score; and
modifying the settings of a post-processor limiter using the identified score information, the modifying comprising:
identifying the genre of the score from a plurality of distinct genres;
identifying the author of the score from a plurality of authors;
identifying values for one or more settings for the limiter corresponding to the identified genre and author, where different values for the settings can be identified for different combinations of genres and authors such that the combination of the identified genre and the identified author has corresponding settings for the limiter that provide an audio output level within a specified range; and
modifying the settings of the limiter including a limiter threshold value and a limiter gain according to the identified settings for the limiter, where the modified settings result in the limiter providing an audio output level within the specified range.

2. (canceled)

3. The method of claim 2, where identifying values for one or more settings includes using a table relating the combination of the identified genre and the identified author with respective settings for the limiter.

4.-5. (canceled)

6. The method of claim 1, further comprising:
reading metadata associated with the score, the metadata including the score information.

7. (canceled)

8. A computer program product, encoded on a non-transitory computer-readable medium, operable to cause data processing apparatus to perform operations comprising:
receiving a selection of an audio score and an input specifying a time length for the audio score, the audio score being a decomposed digital audio data template associated with one or more audio tracks;
automatically identifying score information for the selected audio score, where the score information includes a genre;
generating the selected audio score including retrieving the one or more tracks of digital audio data associated with the audio score and automatically resizing individual tracks of the one or more tracks to cause the audio score to correspond with the specified time length; and
modifying the settings of a post-processor limiter using the identified score information, the modifying comprising:
identifying the genre of the score from a plurality of distinct genres;
identifying values for one or more settings for the limiter corresponding to the identified genre, where different values for the settings can be identified for different genres such that each of the plurality of distinct genres has corresponding settings for the limiter that provide an audio output level within a specified range; and
modifying the settings of the limiter including a limiter threshold value and a limiter gain according to the identified settings for the limiter, where the modified settings result in the limiter providing an audio output level within the specified range.

9. (canceled)

10. The computer program product of claim 9, where identifying settings includes using a table relating genres with settings for one or more post-processors.

11.-12. (canceled)

13. The computer program product of claim 8, further comprising:
reading metadata associated with the score, the metadata including the score information.

14. (canceled)

15. A system comprising:
one or more computers operable to perform operations including:
receiving a selection of an audio score, the audio score being a decomposed digital audio data template associated with a plurality of audio tracks;
automatically identifying score information for the selected audio score, where the score information includes a genre;
mixing the selected audio score including retrieving individual audio tracks of the plurality of audio tracks associated with the audio score and combining, according to a predefined mixing topology, the plurality of tracks into a mixdown track that includes audio data from each of the individual audio tracks; and
modifying, as part of the combining, the settings of a post-processor limiter using the identified score information, the modifying comprising:
identifying the genre of the score from a plurality of distinct genres;
identifying values for one or more settings for the limiter corresponding to the identified genre, where different values for the settings can be identified for different genres such that each of the plurality of distinct genres has corresponding settings for the limiter that provide an audio output level within a specified range; and
modifying the settings of the limiter including a limiter threshold value and a limiter gain according to the identified settings for the limiter, where the modified settings result in the limiter providing an audio output level within the specified range.

17. The system of claim 16, where identifying values for the one or more settings includes using a table relating genres with respective values for the one or more settings.

18.-19. (canceled)

20. The system of claim 15, where the operations further include:
reading metadata associated with the score, the metadata including the score information.

21. (canceled)

22. A method comprising:
receiving a selection of two or more related digital audio tracks;
automatically identifying information associated with the two or more audio tracks, the information including a genre and an author respectively associated with individual tracks of the two or more audio tracks; and
modifying the settings of at least one of one or more post-processors using the genre and the author of the identified information, where the modified settings provide an audio output level within a specified range for audio data mixed from the two or more audio tracks.

23. A computer program product, encoded on a non-transitory computer-readable medium, operable to cause data processing apparatus to perform operations comprising:
receiving a selection of two or more related digital audio tracks to include in a multi-track audio output and an input specifying a time length of the multi-track audio output;
automatically identifying information associated with the two or more audio tracks, the information including a type of audio data;
automatically resizing individual tracks of the two or more tracks to cause the multi-track audio output to correspond with the specified time length; and
modifying the settings of at least one of one or more post-processors using the identified information, where the modified settings provide an audio output level within a specified range for the multi-track audio output.

24. A system comprising:
one or more computers operable to perform operations including:
receiving a selection of two or more related digital audio tracks to include in a multi-track audio output and an input specifying a time length of the multi-track audio output;
automatically identifying information associated with the two or more audio tracks, the information including a genre and an author respectively associated with individual tracks of the two or more audio tracks;
automatically resizing individual tracks of the two tracks to cause the multi-track audio output to correspond with the specified time length; and
modifying the settings of at least one of one or more post-processors using the genre and the author of the identified information, where the modified settings provide an audio output level within a specified range for the multi-track audio output.
